(19) United States
(12) Patent Application Publication
(10) Pub. No.: US 2026/0143788 A1
(43) Pub. Date: May 21, 2026

(54) METHOD FOR MANUFACTURING STACKED DEVICE WITH UNIFORM CUT FIN RECESSES

(71) Applicant: TAIWAN SEMICONDUCTOR MANUFACTURING COMPANY, LTD., Hsinchu (TW)

(72) Inventors: Chun-Yu LIU, New Taipei City (TW); Guan-Ren WANG, Hsinchu (TW); Chu-Hsuan SHA, Taipei City (TW)

(73) Assignee: TAIWAN SEMICONDUCTOR MANUFACTURING COMPANY, LTD., Hsinchu (TW)

(21) Appl. No.: 18/954,630

(22) Filed: Nov. 21, 2024

(51) Int. Cl. H01L 21/822; H01L 21/8238; H01L 27/092; H01L 29/06; H01L 29/423; H01L 29/66; H01L 29/775; H01L 29/786

(52) U.S. Cl. CPC H10D 84/038; H10D 30/014; H10D 30/43; H10D 30/6735; H10D 30/6757; H10D 62/121; H10D 64/017; H10D 84/0167; H10D 84/0188; H10D 84/856; H10D 88/01

(57) ABSTRACT

A method includes forming first and second fin structures over a substrate. The first fin structures are distributed denser than the second fin structures. A first bottom layer of a multi-layer photoresist is deposited over the substrate to cover the first and second fin structures. First and second openings are formed in the first bottom layer and over the first and second fin structures. A second bottom layer of the multi-layer photoresist is deposited over the substrate and fills the first and second openings. A top surface of the second bottom layer directly over the first fin structures is lower than a top surface of the second bottom layer directly over the second fin structures. The first and second fin structures are patterned by using the multi-layer photoresist as an etch mask. A complementary FET including channel layers of one of the first fin structures is formed.

### BACKGROUND

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of an integrated circuit structure (or a semiconductor device) in accordance with some embodiments of the present disclosure.

FIGS. 2-14B illustrate perspective views and cross-sectional views of intermediate stages in the formation of the integrated circuit structure (or a semiconductor device) in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

As used herein, the term “etch selectivity” refers to the ratio of the etch rates of two different materials under the same etching conditions. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9). As used herein, the term “low-k” refers to a low dielectric constant. In the field of semiconductor device structures and manufacturing processes, low-k refers to a dielectric constant that is less than the dielectric constant of SiO₂ (e.g., less than 3.9). As used herein, the term “p-type” defines a structure, layer, and/or region as being doped with p-type dopants, such as boron. As used herein, the term “n-type” defines a structure, layer, and/or region as being doped with n-type dopants, such as phosphorus. As used herein, the term “conductive” refers to an electrically conductive structure, layer, and/or region. As used herein, source/drain region(s) may refer to a source or a drain, individually or collectively dependent upon the context.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure.

The present disclosure is related to integrated circuit structures and methods of forming the same. More particularly, some embodiments of the present disclosure are related to manufacturing methods of stacked GAA devices including modifying morphology of a top surface of photoresists to improve the etching uniformity among regions having features with different densities and/or pitches.

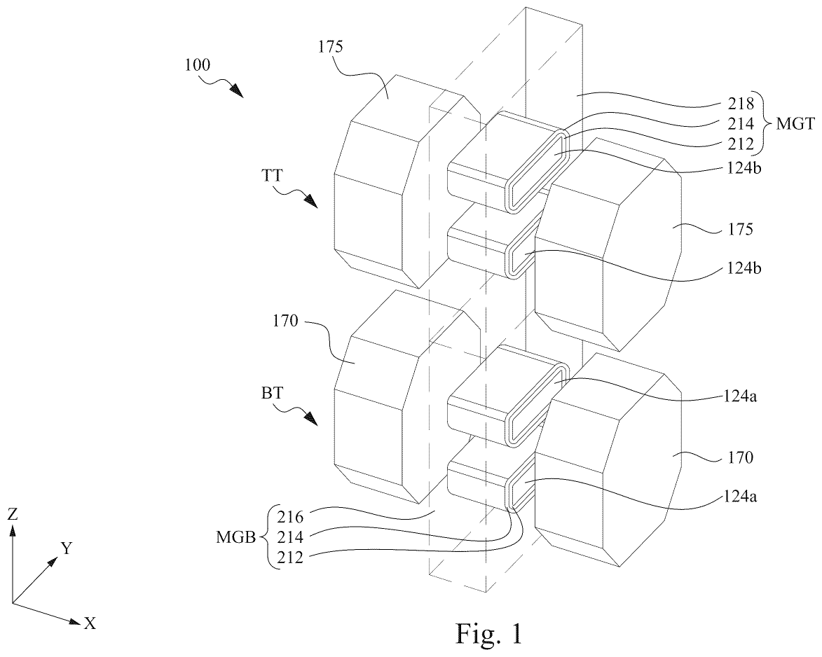

FIG. 1 is a perspective view of an integrated circuit structure (or a semiconductor device) 100 in accordance with some embodiments of the present disclosure. In the present disclosure, a semiconductor device 100 is provided, and its manufacturing method will be disclosed in the following discussion. In addition to the semiconductor device 100, FIG. 1 depicts X-axis, Y-axis, and Z-axis directions. In the semiconductor device 100, a top transistor TT is disposed vertically above a bottom transistor BT. In some embodiments, the bottom transistor BT and the top transistor TT each may be field effect transistor (FET) and may both include gate-all-around (GAA) configuration, and thus the bottom transistor BT and the top transistor TT can also be referred to as GAA FETs. The bottom transistor BT includes epitaxial layers 124a vertically stacked one above another, a gate structure MGB wrapping around each of the epitaxial layers 124a, and first source/drain epitaxy structures 170 on opposite ends of each of the epitaxial layers 124a. Similarly, the top transistor TT includes epitaxial layers 124b vertically stacked one above another, a gate structure MGT wrapping around each of the epitaxial layers 124b, and second source/drain epitaxy structures 175 on opposite ends of each of the epitaxial layers 124b.

The gate structure MGB may include interfacial layers 212, high-k gate dielectric layers 214, and a work function metal layer 216. Similarly, the gate structure MGT may include the interfacial layers 212, the high-k gate dielectric layers 214, and a work function metal layer 218. In some embodiments, the bottom transistor BT has a first conductivity type (e.g., p-type) and the top transistor TT has a second conductivity type (e.g., n-type) different from the first conductivity type. In some embodiments, the bottom transistor BT can be referred to as P-FETs, and the top transistor TT can be referred to as N-FETs.

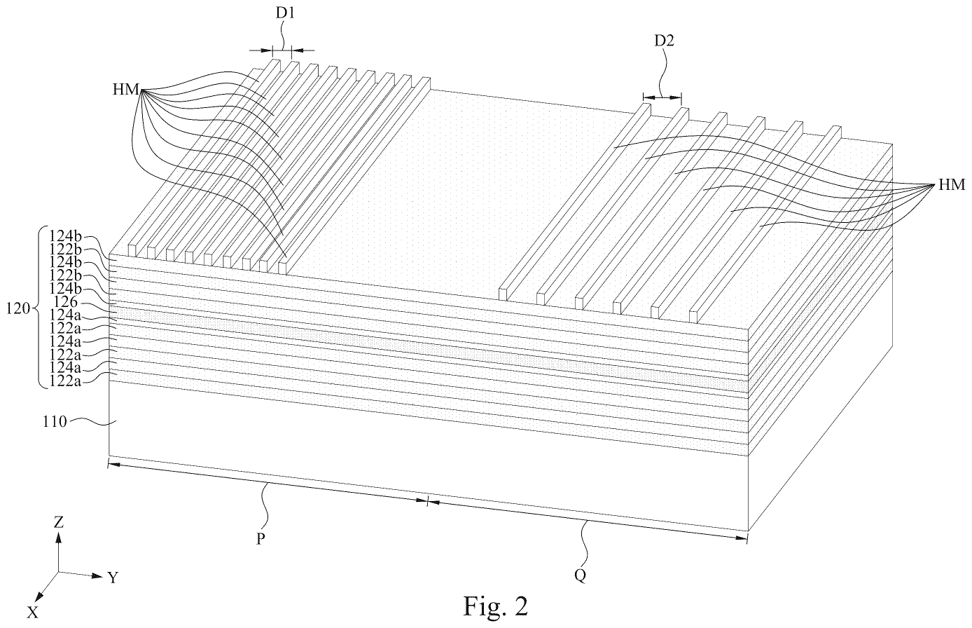

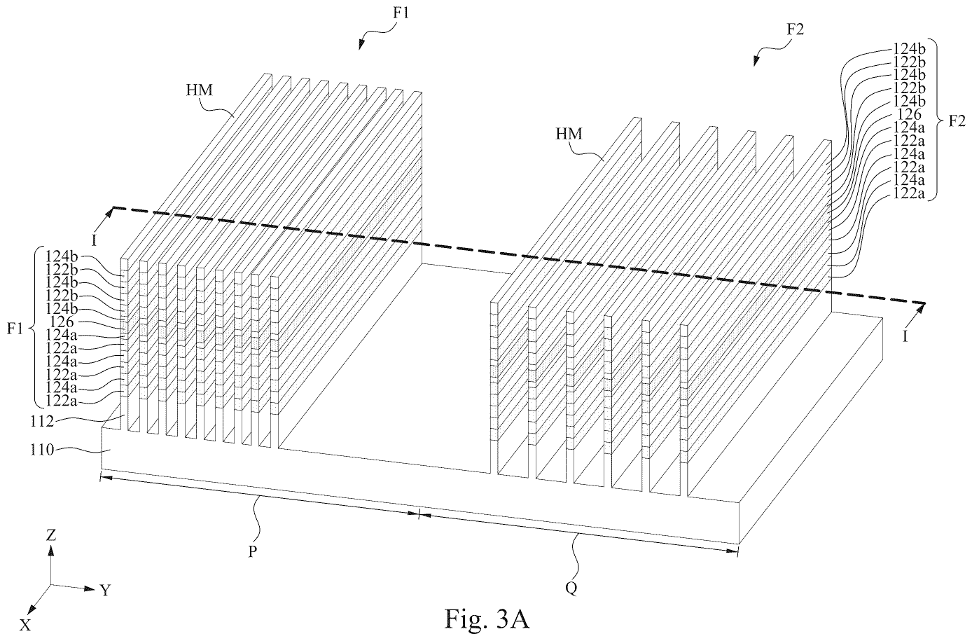

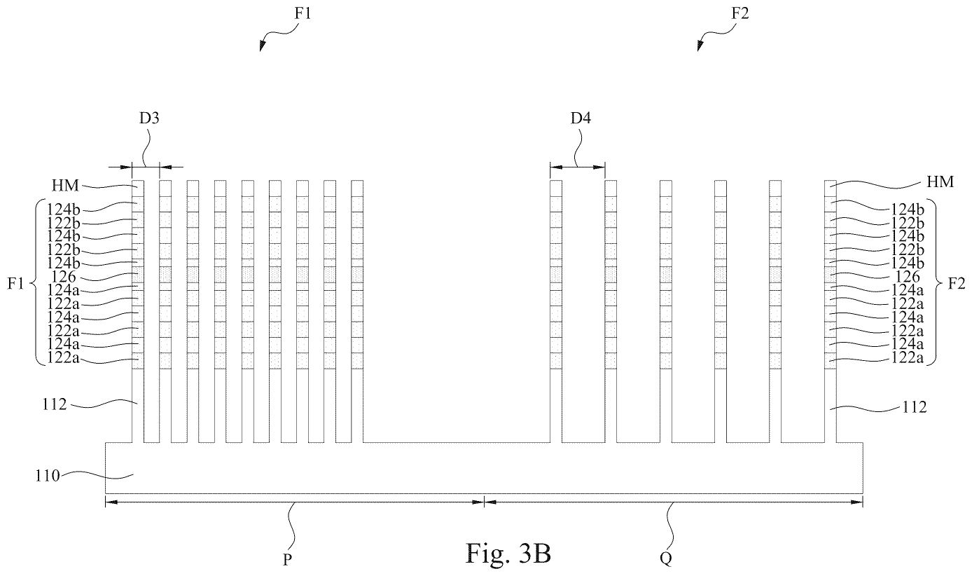

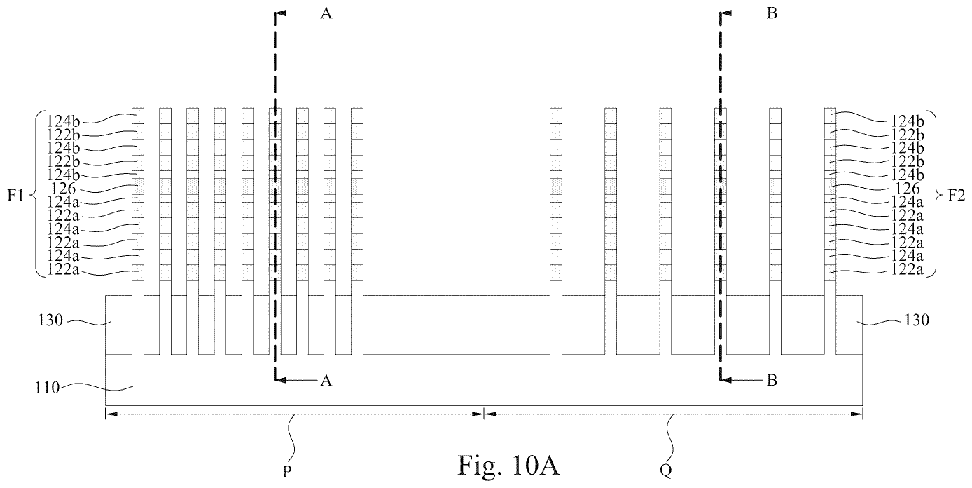

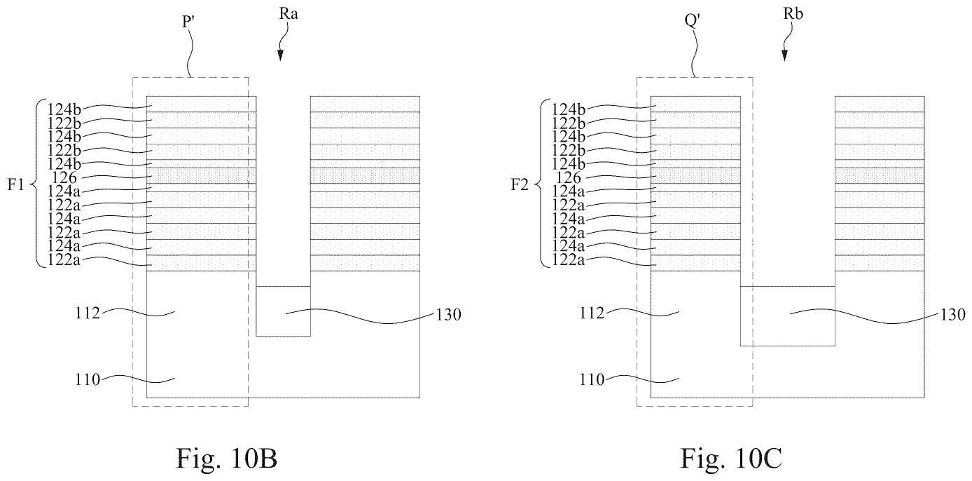

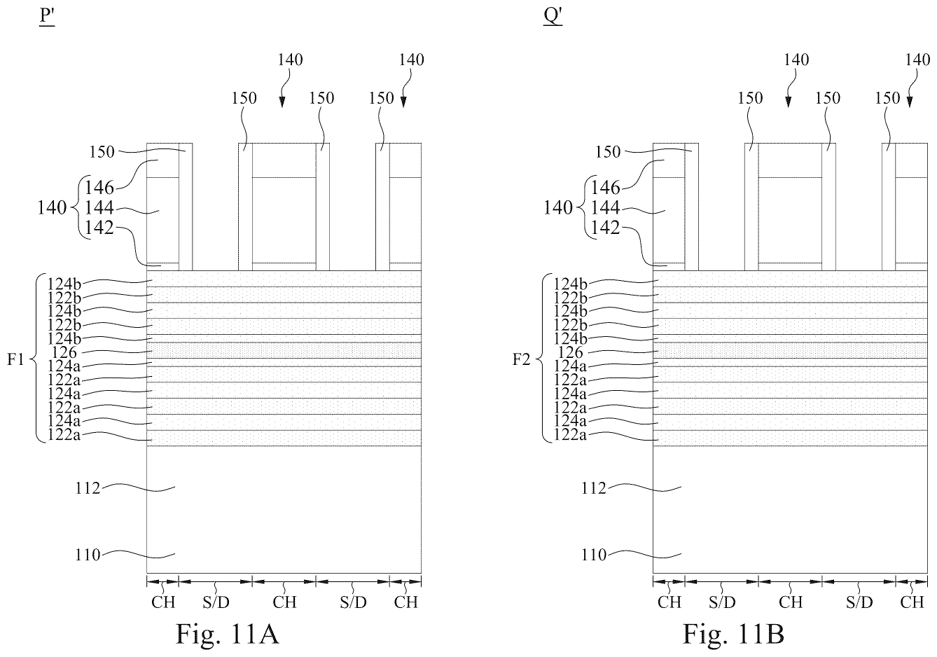

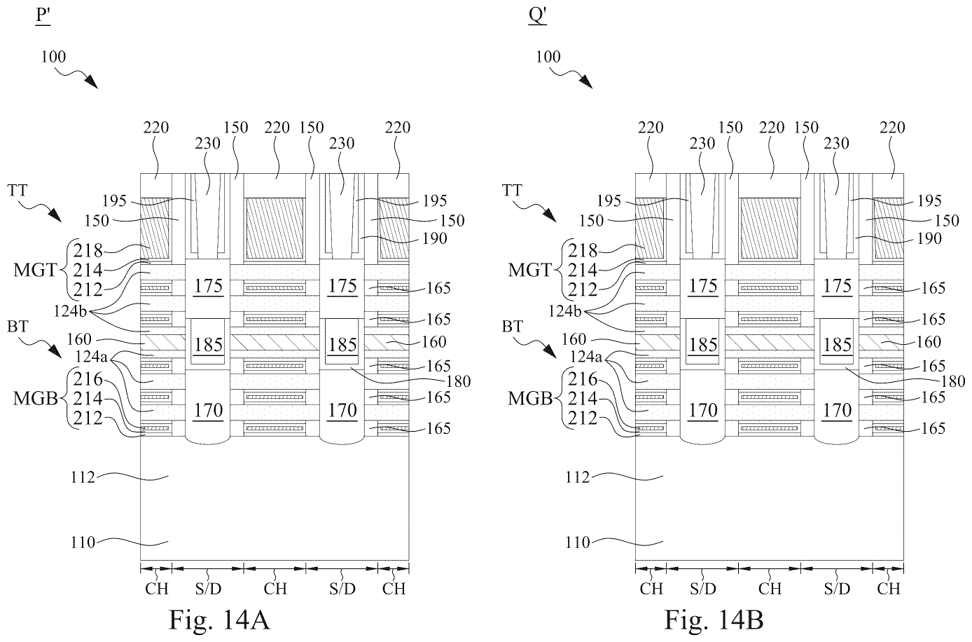

FIGS. 2-14B illustrate perspective views and cross-sectional views of intermediate stages in the formation of the integrated circuit structure (or a semiconductor device) 100 in accordance with some embodiments of the present disclosure. In some embodiments, the semiconductor device 100 in FIGS. 14A and 14B is a complementary FET (CFET) device. In addition to the semiconductor device 100, FIGS. 2-3A depict X-axis, Y-axis, and Z-axis directions. FIGS. 3B, 4-8, and 9A are cross-sectional views of some embodiments of the semiconductor device 100 at intermediate stages along a first cut (e.g., cut I-I in FIG. 3A). FIGS. 11A, 12A, 13A, and 14A are enlarged views of area P′ in FIG. 10B of some embodiments of the semiconductor device 100 at intermediate stages. FIGS. 11B, 12B, 13B, and 14B are enlarged views of area Q′ in FIG. 10C of some embodiments of the semiconductor device 100 at intermediate stages. The formed devices include p-type transistors (such as p-type GAA FETs) and n-type transistors (such as n-type GAA FETs) in accordance with some exemplary embodiments. Throughout the various views and illustrative embodiments, like reference numbers are used to designate like elements. It is understood that additional operations can be provided before, during, and after the processes shown by FIGS. 2-14B, and some of the operations described below can be replaced or eliminated, for additional embodiments of the method. The order of the operations/processes may be interchangeable.

Referring to FIG. 2, an epitaxial stack 120 is formed over a substrate 110. In some embodiments, the substrate 110 may include silicon (Si). Alternatively, the substrate 110 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or combinations thereof) or other appropriate semiconductor materials. In some embodiments, the substrate 110 may include a semiconductor-on-insulator (SOI) structure such as a buried dielectric layer. Also alternatively, the substrate 110 may include a buried dielectric layer such as a buried oxide (BOX) layer, such as that formed by a method referred to as separation by implantation of oxygen (SIMOX) technology, wafer bonding, SEG, or another appropriate method. In some embodiments, the substrate 110 includes a region P and a region Q as shown in FIG. 2.

The epitaxial stack 120 includes epitaxial layers 122a and 122b of a first composition interposed by epitaxial layers 124a and 124b of a second composition arranged in a stacking direction (Z-axis in this case). The epitaxial stack 120 further includes an epitaxial layer 126 between the topmost epitaxial layer 124a and the bottommost epitaxial layer 124b of a third composition. The first, second, and third compositions are different. In some embodiments, the epitaxial layers 122a, 122b, and 126 are SiGe and the epitaxial layers 124a and 124b are silicon (Si). Further, the germanium concentration of the epitaxial layer 126 is higher than the germanium concentration of the epitaxial layer 122a and 122b. However, other embodiments are possible including those that provide for a first composition, a second composition, and a third composition having different etch selectivity.

The epitaxial layers 124a and 124b or portions thereof may form nanostructure channel(s) of the nanostructure transistor. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. For example, the nanostructures are nanosheets, nanowires, nanoslabs, or nanorings, depending on their geometry. The use of the epitaxial layers 124a and 124b to define a channel or channels of a device is further discussed below.

In FIG. 2, the epitaxial layers 124b are disposed above the epitaxial layers 124a. It is noted that three layers of the epitaxial layers 124a and three layers of the epitaxial layers 124b are arranged as illustrated in FIG. 2, which is for illustrative purposes only and not intended to be limiting beyond what is specifically recited in the claims. It can be appreciated that any number of epitaxial layers can be formed in the epitaxial stack 120; the number of layers depending on the desired number of channels regions for the transistor. In some embodiments, the number of each of the epitaxial layers 124a and 124b is between 2 and 10.

As described in more detail below, the epitaxial layers 124a and 124b may serve as channel region(s) for a subsequently-formed semiconductor device and the thickness is chosen based on device performance considerations. The epitaxial layers 122a and 122b in channel regions(s) may eventually be removed and serve to define a vertical distance between adjacent channel region(s) for a subsequently-formed multi-gate device and the thickness is chosen based on device performance considerations. Accordingly, the epitaxial layers 122a and 122b may also be referred to as sacrificial layers, and epitaxial layers 124a and 124b may also be referred to as channel layers.

By way of example, epitaxial growth of the layers of the epitaxial stack 120 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 124a and 124b include the same material as the substrate 110. In some embodiments, the epitaxial layers 122a, 122b, 124a, 124b, and 126 include a different material than the substrate 110. As stated above, in at least some examples, the epitaxial layers 122a, 122b, and 126 include an epitaxially grown silicon germanium (SiGe) layer and the epitaxial layers 124a and 124b include an epitaxially grown silicon (Si) layer. Alternatively, in some embodiments, either of the epitaxial layers 122a, 122b, 124a, 124b, and 126 may include other materials such as germanium, tin, a compound semiconductor such as silicon carbide, gallium arsenide, gallium phosphide, indium phosphide, indium arsenide, and/or indium antimonide, an alloy semiconductor such as SiGe, GeSn, GaAsP, AlInAs, AlGaAs, InGaAs, GaInP, and/or GaInAsP, III-V, or combinations thereof. As discussed, the materials of the epitaxial layers 122a, 122b, 124a, 124b, and 126 may be chosen based on providing differing oxidation and/or etching selectivity properties.

Hard mask layers HM are then formed over the epitaxial stack 120. The hard mask layers HM include a dielectric material, such as silicon oxide, silicon nitride, silicon oxynitride, or any other suitable dielectric material. A photolithography process is performed to form the hard mask layers HM. Specifically, the photolithography process may include forming a photoresist layer (not shown) over a blanket hard mask layer, exposing the photoresist to a pattern, performing post-exposure bake processes, and developing the resist to form a patterned resist. The patterned resist is then used for patterning the blanket hard mask layer to form the hard mask layers HM. A pitch D1 of the hard mask layers HM over the region P of the substrate 110 is different from a pitch D2 of the hard mask layers HM over the region Q of the substrate 110. For example, the pitch D2 is greater than the pitch D1. The hard mask layers HM over the region P is distributed denser than the hard mask layers HM over the region Q.

Reference is made to FIGS. 3A and 3B, where FIG. 3B is a cross-sectional view taken along line I-I of FIG. 3A. Fin structures F1 and F2 extending from the substrate 110 are formed. The fin structures F1 are formed over base portions 112 formed from the region P of the substrate 110, and the fin structures F2 are formed over base portions 112 formed from the region Q of the substrate 110. In various embodiments, each of the fin structures F1 and F2 includes portions of each of the epitaxial layers of the epitaxial stack including epitaxial layers 122a, 122b, 124a, 124b, and 126. The fin structures F1 and F2 may be fabricated using suitable processes including double-patterning or multi-patterning processes.

Specifically, the fin structures F1 and F2 are fabricated using suitable processes including etch processes. The hard mask layers HM are used to protect regions of the substrate 110, and layers formed thereupon, while an etch process forms trenches in unprotected regions through the hard mask layers HM, through the epitaxial stack 120, and into the substrate 110, thereby leaving the fin structures F1 and F2. The trenches may be etched using a dry etch (e.g., reactive ion etching), a wet etch, and/or combination thereof. Numerous other embodiments of methods to form the fin structures F1 and F2 on the substrate may also be used including, for example, defining the fin region (e.g., by mask or isolation regions) and epitaxially growing the epitaxial stack 120 in the form of the fin structures F1 and F2.

As mentioned above, the hard mask layers HM have different pitches in different regions P and Q. Therefore, the fin structures F1 have a pitch D3 different from a pitch D4 of the fin structures F2. For example, the pitch D4 of the fin structures F2 is greater than the pitch D3 of the fin structures F1. That is, the fin structures F1 are distributed denser than the fin structures F2. As such, the region P including denser fin structures F1 may be referred to be a dense region, and the fin structures F1 may be referred to be dense features (or dense structures) while the region Q including loose fin structures F2 may be referred to be an isolated region, and the fin structures F2 may be referred to be isolated features (or isolated structures). In some embodiments, the ratio of the pitch D4 to the pitch D3 (i.e., D4/D3) may be in a range of about 2 and about 3000.

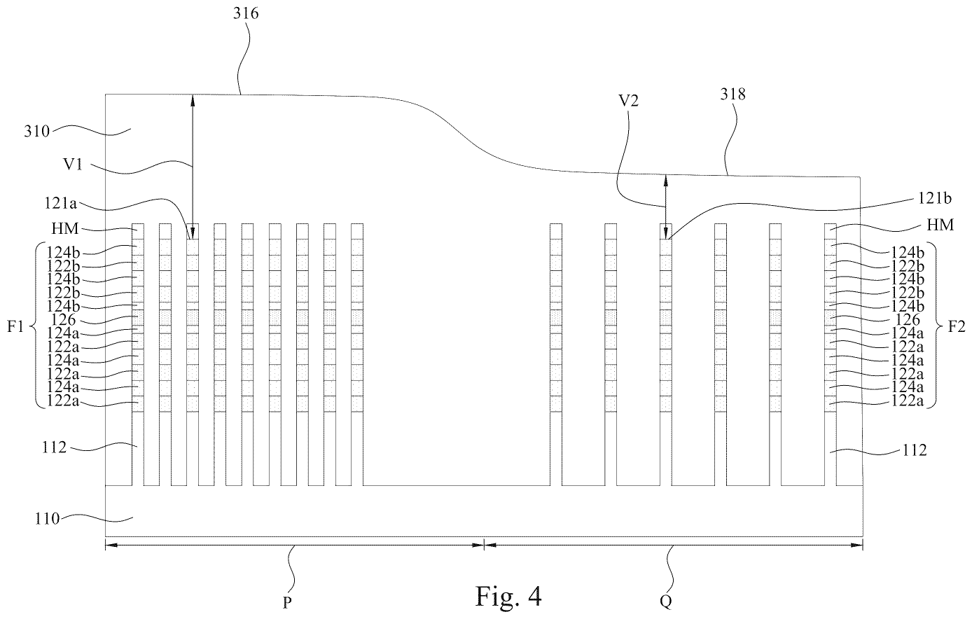

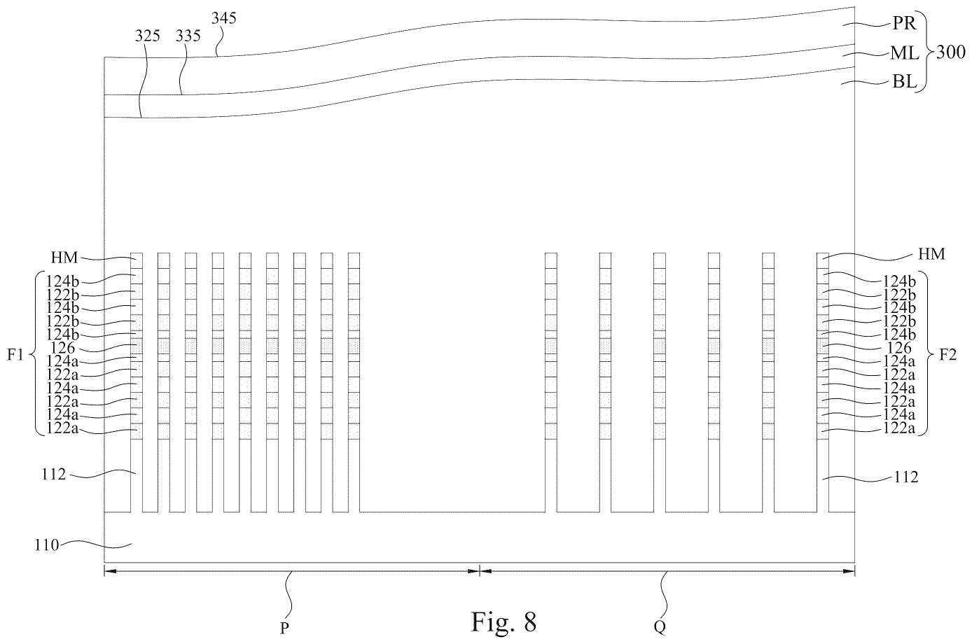

Reference is made to FIG. 4. A cut fin process is performed. Specifically, one or more of the fin structures F1 and F2 are cut in the X direction (see FIG. 3A) according to various circuit design requirements. In some embodiments, a multi-layer photoresist 300 (see FIG. 8) is formed to pattern the fin structures F1 and F2. Specifically, a first bottom layer 310 of the multi-layer photoresist 300 is formed over the substrate 110. As such, the first bottom layer 310 covers the fin structures F1 over the region P and the fin structures F2 over the region Q. In some embodiments, the first bottom layer 310 may include a carbon layer or a hydrogen layer deposited using a vapor deposition technique or a spin-on technique. The first bottom layer 310 may be formed of a polymer in some embodiments. The first bottom layer 310 may also be a bottom anti-reflective coating (BARC) layer or an ashing removal dielectric (ARD) layer (such as amorphous carbon).

As mentioned above, the fin structures F1 and F2 have different pitches (and thus different densities), the spacing between the neighboring fin structures F1 and the spacing between the neighboring fin structures F2 are different. Such spacing difference results in uneven distributions of the first bottom layer 310. As shown in FIG. 4, a top surface 316 of the first bottom layer 310 directly over the fin structures F1 and the region P is higher than a top surface 318 of the first bottom layer 310 directly over the fin structures F2 and the region Q since there are larger gaps between the fin structures F2 to be filled with the first bottom layer 310 than between the fin structures F1. Stated another way, a vertical distance V1 between the top surface 316 of the first bottom layer 310 and a top surface 121a of the fin structures F1 is greater than a vertical distance V2 between the top surface 318 of the first bottom layer 310 and a top surface 121b of the fin structures F2. Such uneven distribution of the first bottom layer 310 may result in different depths of the cut fin recesses. For example, in the same recess etching process, the cut fin recesses in the region P may be too deep while the cut fin recesses in the region Q are not deep enough. As such, a correlation process is performed to solve this issue.

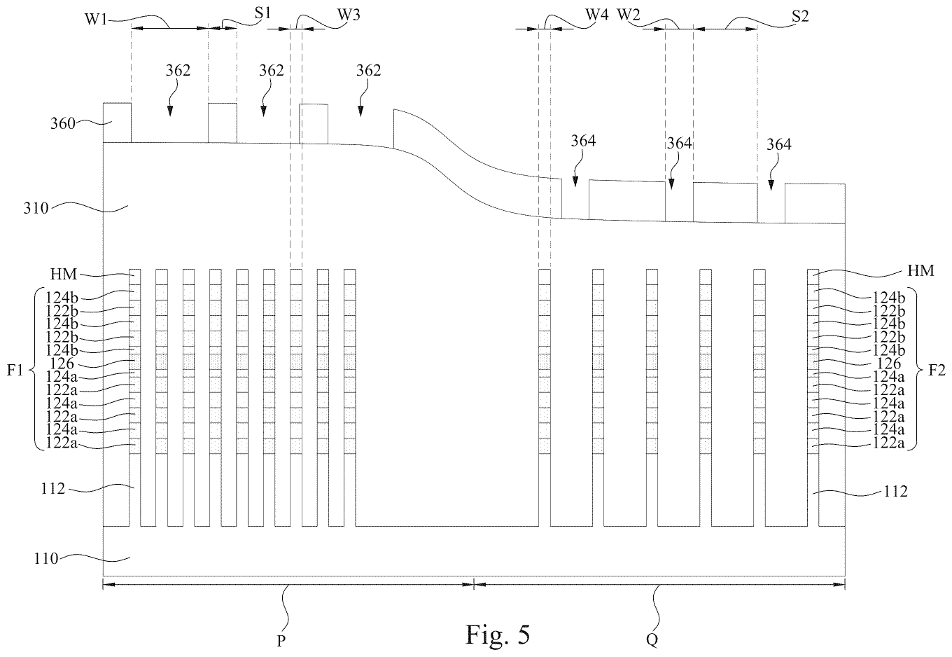

Reference is made to FIG. 5. A first photoresist layer 360 is formed over the first bottom layer 310. The first photoresist layer 360 includes a plurality of first openings 362 directly over the region P and a plurality of second openings 364 directly over the region Q. A width W1 of the first openings 362 is greater than a width W2 of the second openings 364. Further, the widths W1 and W2 are greater than a width W3 of the fin structures F1 and a width W4 of the fin structures F2. A first spacing S1 of the first openings 362 is narrower than a second spacing S2 of the second openings 364. The first openings 362 and the second openings 364 may be squares or rectangles in a cross-sectional view.

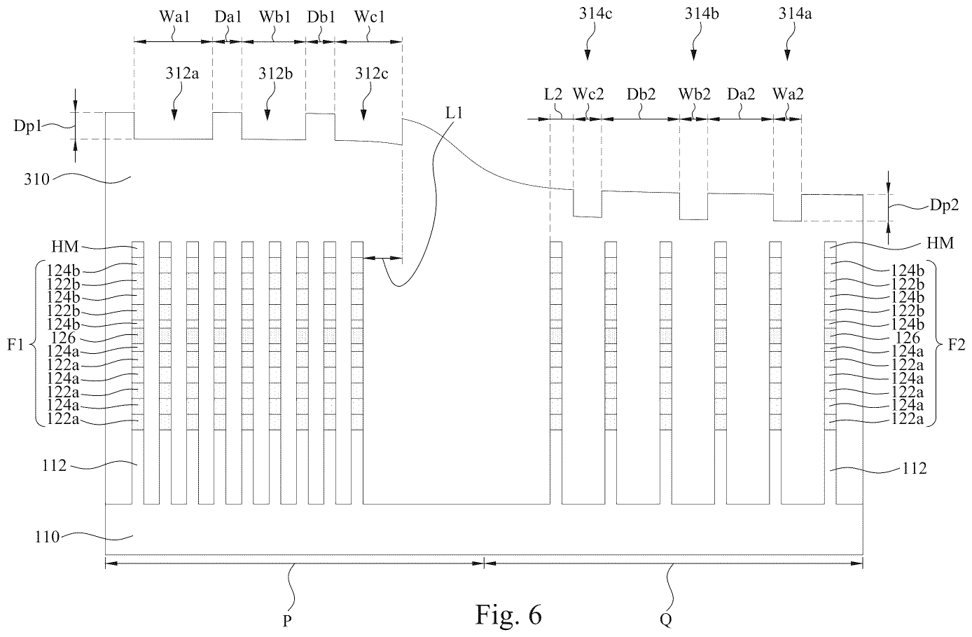

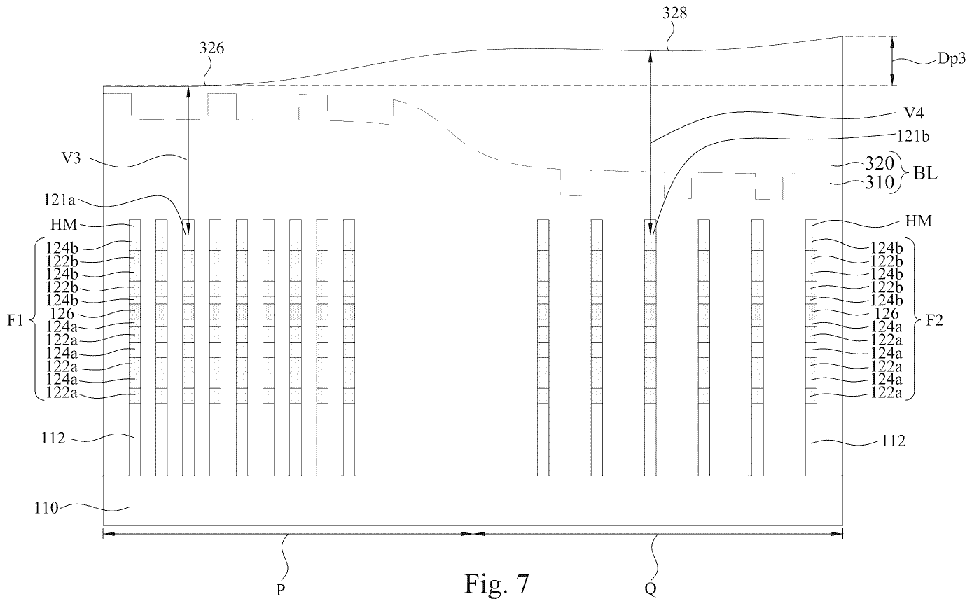

Reference is made to FIGS. 5 and 6. The first bottom layer 310 is patterned by using the first photoresist layer 360 as etch masks. A plurality of first openings 312a, 312b, and 312c are formed in the first bottom layer 310 and directly over the first fin structures F1 and the region P and a plurality of second openings 314a, 314b, and 314c are formed in the first bottom layer 310 and directly over the second fin structures F2 and the region Q. Specifically, an etching process is performed to the first bottom layer 310, wherein CH₄, CHₓF_{y}, CO₂, SO₂, COS may be used as the etching gases. These etching gases are benefit for protecting the sidewalls of the first openings 312a-312c and the second openings 314a-314c, such that the sidewalls of the first openings 312a-312c and the second openings 314a-314c can be straight and substantially vertical to the bottom surface of the substrate 110. The straight sidewalls of the first openings 312a-312c and the second openings 314a-314c are benefit for controlling the levels of the top surfaces 326 and 328 of the following formed second bottom layer 320 (see FIG. 7).

It is noted that three of the first openings 312a-312c and three of the second openings 314a-314c are arranged as illustrated in FIG. 6, which is for illustrative purposes only and not intended to be limiting beyond what is specifically recited in the claims. It can be appreciated that any number of openings can be formed in the first bottom layer 310.

Sizes (or widths or diameters) Wa1, Wb1, Wc1, Wa2, Wb2, and Wc2 are in a range of about 0.1 μm and about 1000 μm. The sizes Wa1, Wb1, and Wc1 are larger than the sizes Wa2, Wb2, and Wc2 by, for example, about 10 times to about 10000 times, depending on the values of the pitches D3 and D4 (see FIG. 3B). The sizes Wa1, Wb1, and Wc1 may be the same or different but of the same order of magnitude, and the sizes Wa2, Wb2, and Wc2 may be the same or different but of the same order of magnitude. Further, the sizes Wa1, Wb1, Wc1, Wa2, Wb2, and Wc2 are larger than the widths W3 and W4 (see FIG. 5) of the fin structures F1 and F2. It is noted that when two numbers are described as being of the same order of magnitude, it means that their exponents in scientific notation are identical or nearly identical.

In some embodiments, the size Wc1 of the first opening 312c, which is near the edge area of the whole fin structures F1 and most near the region Q, is smaller than the size Wb1 of the first opening 312b and/or the size Wa1 of the first opening 312a, which are over the center of the whole fin structures F1. In some embodiments, the size Wc1 is about 50% to about 100% of the size Wa1 (Wb1). In some embodiments, the size Wc2 of the second opening 314c, which is near the edge area of the whole fin structures F2 and most near the region P, is smaller than the size Wb2 of the second opening 314b and/or the size Wa2 of the second opening 314a, which are near the center area of the whole fin structures F2. In some embodiments, the size Wc2 is about 50% to about 100% of the size Wa2 (Wb2).

The first opening 312a is separated from the first opening 312b by a distance Da1, and the first opening 312b is separated from the first opening 312c by a distance Db1. The distances Da1 and Db1 are the same or different. In the case that the distances Da1 and Db1 are different, the smallest of the distances Da1 and Db1 may be about 30% of the sizes Wal, Wb1, and/or Wc1. The second opening 314a is separated from the second opening 314b by a distance Da2, and the second opening 314b is separated from the second opening 314c by a distance Db2. The distances Da2 and Db2 are the same or different. In the case that the distances Da2 and Db2 are different, the smallest of the distances Da2 and Db2 may be the same size of the sizes Wa2, Wb2, and/or Wc2. That is, the distances Da2 and Db2 may be equal to or larger than the sizes Wa2, Wb2, and/or Wc2. Further, the distances Da1 and Db1 are narrower than the distances Da2 and Db2.

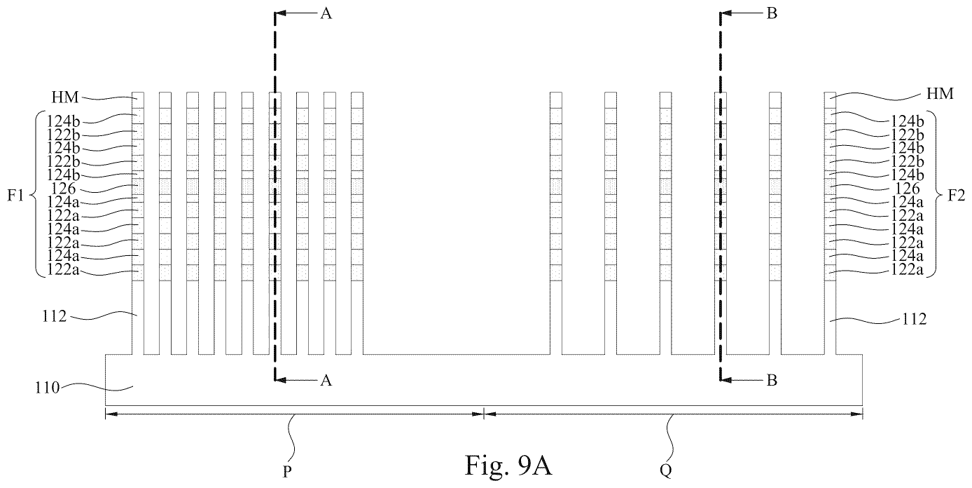

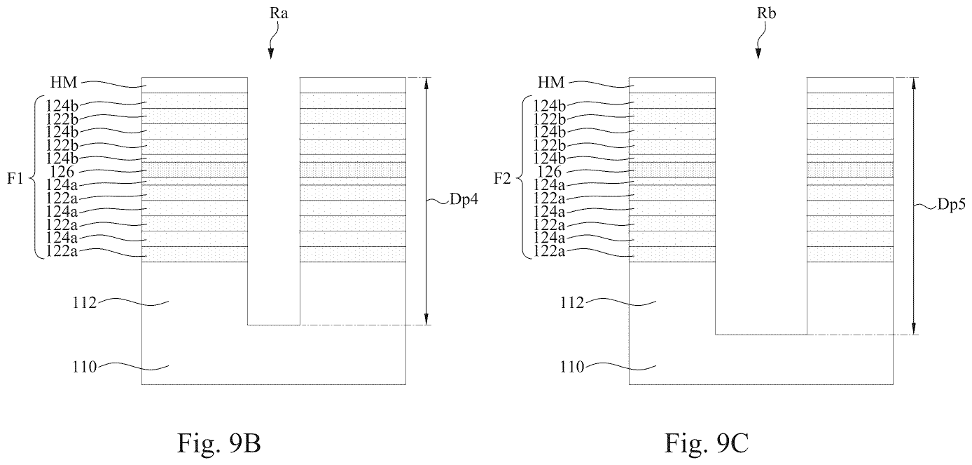

A sidewall of the first opening 312c, which is most near the second openings 314a-314c, is separated from a sidewall of the fin structure F1, which is most near the fin structures F2, by a lateral distance L1, which is in a range of about 0 and about 5 times of the sizes Wal, Wb1, and/or Wc1 and/or the distances Da1 and Db1. A sidewall of the second opening 314c, which is most near the first openings 312a-312c, is separated from a sidewall of the fin structure F2, which is most near the fin structures F1, by a lateral distance L2, which is in a range of about 0 and about 5 times of the sizes Wa2, Wb2, and/or Wc2 and/or the distances Da2 and Db2. In some embodiments, a depth Dp1 and a depth Dp2 are in a range of about 10 nm and about 100 nm. As shown in FIG. 6, the first openings 312a-312c and the second openings 314a-314c do not expose the fin structures F1 and F2. If the sizes Wal, Wb1, Wc1, Wa2, Wb2, Wc2, the distances Da1, Db1, Da2, Db2, the lateral distances L1, L2, and the depths Dp1, Dp2 are out of the aforementioned range, the following formed second bottom layer 320 (see FIG. 7) may not have a desired top surface, and the following formed recesses Ra and Rb (see FIGS. 9B and 9C) may not have substantially uniform depth.

Reference is made to FIG. 7. A second bottom layer 320 is deposited over the first bottom layer 310 and fills the first openings 312a-312c and the second openings 314a-314c. The second bottom layer 320 and the first bottom layer 310 have substantially the same materials and compositions. That is, the second bottom layer 320 may also be a BARC layer or an ARD layer. Therefore, the second bottom layer 320 and the first bottom layer 310 have substantially the same etching selectivity and substantially the same etching rate under the same etching condition. Therefore, the first bottom layer 310 and the second bottom layer 320 together may be referred to as a bottom layer BL. In some embodiments, the second bottom layer 320 is deposited using a vapor deposition technique or a spin-on technique.

As mentioned above, the sizes Wal, Wb1, Wc1 of the first openings 312a-312c (see FIG. 6) are larger than the sizes Wa2, Wb2, Wc2 of the second openings 314a-314c (see FIG. 6), there are more spaces to be filled in the first openings 312a-312c. As such, the top surface 326 of the second bottom layer 320 directly over the fin structures F1 and the region P is lower than the top surface 328 of the second bottom layer 320 directly over the fin structures F2 and the region Q by a vertical distance Dp3. In some embodiments, the vertical distance Dp3 is in a range of about 10 nm and about 100 nm. If the vertical distance Dp3 is out of this range, the following formed recesses Ra and Rb (see FIGS. 9B and 9C) may not have substantially uniform depth. Stated another way, a vertical distance V3 between the top surface 326 of the second bottom layer 320 and the top surface 121a of the fin structures F1 is less than a vertical distance V4 between the top surface 328 of the second bottom layer 320 and the top surface 121b of the fin structures F2.

Further, since the sizes Wa1, Wb1, and Wc1 are of the same order of magnitude, the top surface 326 is substantially flat. Similarly, since the sizes Wa2, Wb2, and Wc2 are of the same order of magnitude, the top surface 328 is substantially flat. The substantially flat top surfaces 326 and 328 are benefit for etching uniformity for the recesses Ra and Rb.

Reference is made to FIG. 8. Subsequently, a middle layer ML and a second photoresist layer PR of the multi-layer photoresist 300 are deposited over the bottom layer BL in sequence. In some embodiments, the middle layer ML may include a silicon oxide deposited using a vapor deposition technique or a spin-on technique. In some embodiments, the middle layer ML may include an inorganic material, which may be a nitride (such as silicon nitride), an oxynitride (such as silicon oxynitride), an oxide (such as silicon oxide), or the like. The photoresist layer PR may be formed of a photosensitive material, which includes organic materials, and may be a positive photosensitive material or a negative photosensitive material. The middle layer ML may have a high etching selectivity relative to the photoresist layer PR and the bottom layer BL. The various layers of the multi-layer photoresist 300 may be blanket deposited sequentially using, for example, spin-on processes. Other processes and materials may be used. The bottom layer BL and the middle layer ML have different compositions. The bottom layer BL and the middle layer ML may have different dissolution properties (e.g., dissolution rates) in a developer solution. For example, the middle layer ML may have a lower dissolution rate as compared to the bottom layer BL.

In some embodiments, the top surface 335 of the middle layer ML is substantially conformal to the top surface 325 of the bottom layer BL, and the top surface 345 of the second photoresist layer PR is substantially conformal to the top surface 335 of the middle layer ML.

Reference is made to FIGS. 9A-9C, where FIG. 9B is a cross-sectional view taken along line A-A of FIG. 9A, and FIG. 9C is a cross-sectional view taken along line B-B of FIG. 9A. The fin structures F1 and F2 are patterned by using the multi-layer photoresist 300 (see FIG. 8) as an etch mask. Specifically, the second photoresist layer PR of the multi-layer photoresist 300 is patterned. Subsequently, using the second photoresist layer PR as an etch mask, the middle layer ML and the bottom layer BL of the multi-layer photoresist 300 are etched by various methods, including a dry etch, a wet etch, or combinations of dry etch and wet etch. Then, portions of the hard mask layers HM disposed on the fin structures F1 and F2 are removed (or etched). Next, at least portions of the fin structures F1 and F2 are recessed (or etched or removed). The dry etching process may implement CF₄, SiCl₄, other suitable gases and/or plasmas, and/or combinations thereof. The etching process may include a multiple-step etching to gain etch selectivity, flexibility and desired etch profile. The etching process is performed further by tuning pressure thereof for byproduct pumping control to achieve similar etching rate in the regions P and Q. Therefore, at least one recess Ra is formed in at least one of the fin structures F1 and at least one recess Rb is formed in at least one of the fin structures F2. Due to the morphology of the bottom layer BL and the etching parameters, a depth Dp4 of the recess Ra is substantially the same as a depth Dp5 of the recess Rb.

Reference is made to FIGS. 10A-10C, where FIG. 10B is a cross-sectional view taken along line A-A of FIG. 10A, and FIG. 10C is a cross-sectional view taken along line B-B of FIG. 10A. Next, isolation structures 130 are formed to surround the fin structures F1 and F2. The isolation structures 130 may include a liner oxide (not shown). The liner oxide may be formed of a thermal oxide formed through a thermal oxidation of a surface layer of the substrate 110. The liner oxide may also be a deposited silicon oxide layer formed using, for example, Atomic Layer Deposition (ALD), High-Density Plasma Chemical Vapor Deposition (HDPCVD), or Chemical Vapor Deposition (CVD). The isolation structures 130 may also include a dielectric material over the liner oxide, and the dielectric material may be formed using flowable chemical vapor deposition (FCVD), spin-on coating, or the like.

The isolation structures 130 are then planarized, such that the hard mask layers HM (see FIGS. 9A-9C) are removed, and the top surfaces of the fin structures F1 and F2 are exposed. Subsequently, the isolation structures 130 are recessed, so that the top portions of the fin structures F1 and F2 protrude higher than the top surfaces of the neighboring isolation structures 130. The etching may be performed using a dry etching process, wherein NH₃ and NF₃ are used as the etching gases. In accordance with alternative embodiments of the present disclosure, the recessing of the isolation structures 130 is performed using a wet etch process. The etching chemical may include diluted HF, for example.

Reference is made to FIGS. 11A and 11B, where FIG. 11A is an enlarged view of area P′ in FIG. 10B in the following stages of manufacturing the semiconductor device 100, and FIG. 11B is an enlarged view of area Q′ in FIG. 10B in the following stages of manufacturing the semiconductor device 100. A plurality of CFET, which include the epitaxial layers 124a and 124b as their channel layers, are formed. Specifically, dummy gate structures 140 are formed over the substrate 110 and across the fin structures F1 and F2. The portions of the fin structures F1 and F2 underlying the dummy gate structures 140 may be referred to as channel regions CH. The dummy gate structures 140 may also define source/drain regions S/D of the fin structures F1 and F2, for example, the regions of the fin structures F1 and F2 adjacent and on opposite sides of the channel regions CH.

Dummy gate formation operation forms a dummy gate dielectric layer, a dummy gate electrode layer and a hard mask which may include multiple layers (e.g., a nitride layer and an oxide layer) over the dummy gate electrode layer. The hard mask is then patterned, followed by patterning the dummy gate electrode layer by using the patterned hard mask as an etch mask. The etch process may include a wet etch, a dry etch, and/or combinations thereof. As such, dummy gate structures 140 each including a dummy gate dielectric layer 142, a dummy gate electrode layer 144 and a hard mask layer 146 (e.g., a nitride layer and an oxide layer) are formed.

After the formation of the dummy gate structures 140 is completed, gate spacers 150 are formed on opposite sidewalls of the dummy gate structures 140. For example, a spacer material layer is deposited on the substrate 110. The spacer material layer may be a conformal layer that is subsequently etched back to form gate sidewall spacers. In the illustrated embodiments, a spacer material layer is disposed conformally on top and sidewalls of the dummy gate structures 140. The spacer material layer may include a dielectric material such as silicon oxide, silicon nitride, silicon carbide, silicon oxynitride, SiCN films, silicon oxycarbide, SiOCN films, and/or combinations thereof. In some embodiments, the spacer material layer includes multiple layers, such as a first spacer layer and a second spacer layer formed over the first spacer layer. By way of example, the spacer material layer may be formed by depositing a dielectric material over the dummy gate structures 140 using suitable deposition processes. An anisotropic etching process is then performed on the deposited spacer material layer to expose portions of the fin structures F1 and F2 not covered by the dummy gate structures 140 (e.g., over the source/drain regions S/D of the fin structures F1 and F2). Portions of the spacer material layer directly above the dummy gate structures 140 may be completely removed by this anisotropic etching process. Portions of the spacer material layer on sidewalls of the dummy gate structures 140 may remain, forming gate sidewall spacers, which are denoted as the gate spacers 150, for the sake of simplicity.

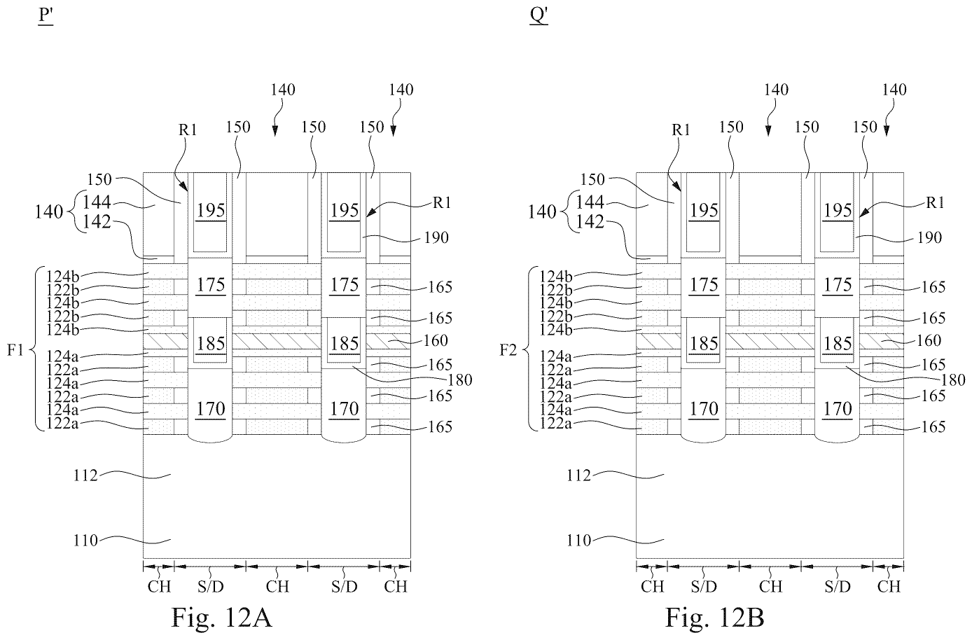

Next, as illustrated in FIGS. 12A and 12B, exposed portions of the fin structures F1 and F2 that extend laterally beyond the gate spacers 150 (e.g., in source/drain regions S/D of the fin structures F1 and F2) are etched by using, for example, an anisotropic etching process that uses the dummy gate structures 140 and the gate spacers 150 as an etch mask, resulting in recesses R1 into the fin structures F1 and F2. After the anisotropic etching, end surfaces of the epitaxial layers 122a-122b, 124a-124b, and 126 and respective outermost sidewalls of the gate spacers 150 are substantially coterminous, due to the anisotropic etching. In some embodiments, the anisotropic etching may be performed by a dry chemical etch with a plasma source and a reaction gas. The plasma source may be an inductively coupled plasma (ICP) source, a transformer coupled plasma (TCP) source, an electron cyclotron resonance (ECR) source or the like, and the reaction gas may be, for example, a fluorine-based gas (such as SF₆, CH₂F₂, CH₃F, CHF₃, or the like), chloride-based gas (e.g., Cl₂), hydrogen bromide gas (HBr), oxygen gas (O₂), the like, or combinations thereof.

The epitaxial layers 126 (see FIGS. 11A and 11B) are removed, resulting in openings between the topmost epitaxial layer 124a and the bottommost epitaxial layer 124b. Subsequently, middle dielectric isolators 160 are filled in the openings, respectively, such that the middle dielectric isolators 160 are between and in contact with the topmost epitaxial layer 124a and the bottommost epitaxial layer 124b. For example, a dielectric material layer is formed to fill the opening. The dielectric material layer may be a low-k dielectric material, such as SiO₂, SiN, SiC, SiON, SiCN, or SiOCN, and may be formed by a suitable deposition method, such as ALD. In some embodiments, the dielectric material layer is intrinsic or un-doped with impurities. The dielectric material layer can be formed using CVD, including LPCVD and PECVD, PVD, ALD, or other suitable processes.

After the deposition of the dielectric material layer, an anisotropic etching process may be performed to remove the dielectric material layer outside the openings, such that portions of the deposited dielectric material layer that fill the openings are left. After the etching process, the remaining portions of the deposited spacer material in the openings are denoted as the middle dielectric isolators 160, for the sake of simplicity. The middle dielectric isolators 160 serve to isolate the epitaxial layers 124a from the epitaxial layers 124b.

The epitaxial layers 122a and 122b are then laterally or horizontally recessed by using suitable etch techniques, resulting in lateral recesses each vertically between corresponding epitaxial layers 124a and 122b. These operations may be performed by using selective etching processes. In some embodiments, the selective dry etching etches SiGe at a faster etch rate than it etches Si.

Subsequently, inner dielectric spacers 165 are filled in the recesses, respectively. For example, spacer material layers are formed and then trimmed to fill the recesses. The spacer material layer may be a low-k dielectric material, such as SiO₂, SiN, SiC, SiON, SiCN, or SiOCN, and may be formed by a suitable deposition method, such as ALD. In some embodiments, the spacer material layer is intrinsic or un-doped with impurities. The spacer material layer can be formed using CVD, including LPCVD and PECVD, PVD, ALD, or other suitable processes.

Next, first source/drain epitaxial structures 170, a first contact etch stop layer (CESL) 180, a first interlayer dielectric (ILD) layer 185, second source/drain epitaxial structures 175, a second CESL 190, and a second ILD layer 195 are sequentially formed the recesses R1 of the fin structures F1 and F2. The first source/drain epitaxial structures 170 are on opposite sides and connected to the epitaxial layers 124a and spaced apart from the epitaxial layers 124b. The second source/drain epitaxial structures 175 are on opposite sides and connected to the epitaxial layers 124b and spaced apart from the epitaxial layers 124a. The first source/drain epitaxial structures 170 and second source/drain epitaxial structures 175 may be formed by performing an epitaxial growth process that provides an epitaxial material on the fin structures F1 and F2. In some embodiments, the lattice constants of the first source/drain epitaxial structures 170 are different from the lattice constant of the epitaxial layers 124a, so that the epitaxial layers 124a can be strained or stressed by the first source/drain epitaxial structures 170 to improve carrier mobility of the semiconductor device and enhance the device performance. Similarly, the lattice constants of the second source/drain epitaxial structures 175 are different from the lattice constant of the epitaxial layers 124b. The epitaxy processes include CVD deposition techniques (e.g., PECVD, vapor-phase epitaxy (VPE) and/or ultra-high vacuum CVD (UHV-CVD)), molecular beam epitaxy, and/or other suitable processes. The epitaxy process may use gaseous and/or liquid precursors, which interact with the composition of the epitaxial layers 124a or 124b.

In some embodiments, the first source/drain epitaxial structures 170 and the second source/drain epitaxial structures 175 may include Ge, Si, GaAs, AlGaAs, SiGe, GaAsP, SiP, or other suitable material. The first source/drain epitaxial structures 170 and the second source/drain epitaxial structures 175 may be in-situ doped during the epitaxial process by introducing doping species including: p-type dopants, such as boron or BF₂; n-type dopants, such as phosphorus or arsenic; and/or other suitable dopants including combinations thereof. If the first source/drain epitaxial structures 170 and/or the second source/drain epitaxial structures 175 are not in-situ doped, an implantation process (i.e., a junction implant process) is performed to dope the first source/drain epitaxial structures 170 and/or second source/drain epitaxial structures 175.

The first CESL 180 is formed on the substrate 110 and covers the first source/drain epitaxial structures 170. The second CESL 190 covers the second source/drain epitaxial structures 175. In some examples, the first CESL 180 and the second CESL 190 include a silicon nitride layer, silicon oxide layer, a silicon oxynitride layer, and/or other suitable materials. The first CESL 180 and the second CESL 190 may be formed by plasma-enhanced chemical vapor deposition (PECVD) process and/or other suitable deposition or oxidation processes.

The first ILD layer 185 is formed over the first CESL 180, and the second ILD layer 195 is formed over the second CESL 190. In some embodiments, the first ILD layer 185 and the second ILD layer 195 include materials such as tetraethylorthosilicate (TEOS)-formed oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials having a different etch selectivity than the first CESL 180. The first ILD layer 185 and the second ILD layer 195 may be deposited by a PECVD process or other suitable deposition technique.

In some examples, after depositing the second ILD layer 195, a planarization process may be performed to remove excessive materials of the second ILD layer 195. For example, a planarization process includes a chemical mechanical planarization (CMP) process which removes portions of the second ILD layer 195 and the second CESL 190 overlying the dummy gate structures 140 and planarizes a top surface of the semiconductor device 100. In some embodiments, the CMP process also removes hard mask layers 146 (as shown in FIGS. 11A and 11B) and exposes the dummy gate electrode layers 144.

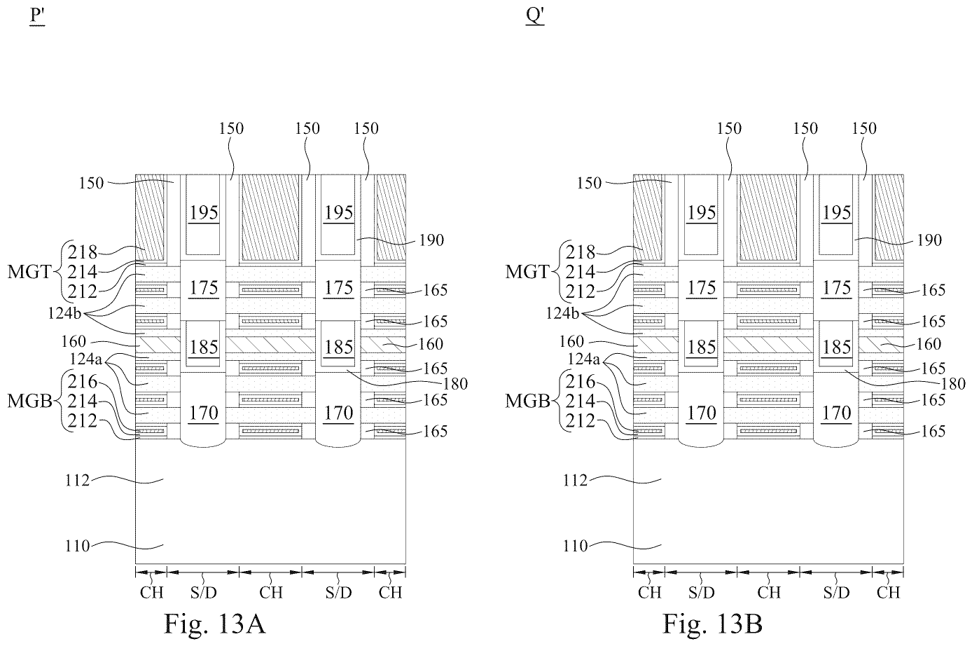

Reference is made to FIGS. 13A and 13B. Thereafter, a gate replacement process is performed. Specifically, the dummy gate electrode layers 144 and the dummy gate dielectric layers 142 are removed first, and then the epitaxial layers (i.e., sacrificial layers) 122a and 122b are removed. In some embodiments, the dummy gate electrode layers 144 are removed by using a selective etching process (e.g., selective dry etching, selective wet etching, or combinations thereof) that etches the materials in dummy gate electrode layers 144 at a faster etch rate than it etches other materials (e.g., the gate spacers 150 and/or the second ILD layer 195), thus resulting in gate trenches between the gate spacers 150, with the epitaxial layers 122a and 122b exposed in the gate trench. Subsequently, the epitaxial layers 122a and 122b in the gate trenches are removed by using another selective etching process that etches the epitaxial layers 122a and 122b at a faster etch rate than it etches the epitaxial layers 124a and 124b, thus forming openings between neighboring epitaxial layers (i.e., channel layers) 124a and 124b. In this way, the epitaxial layers 124a and 124b become nanosheets suspended over the substrate 110. This operation is also called a channel release process. In some embodiments, the epitaxial layers 124a and 124b can be interchangeably referred to as nanostructure (nanowires, nanoslabs and nanorings, nanosheet, etc., depending on their geometry). For example, in some other embodiments the epitaxial layers 124a and 124b may be trimmed to have a substantial rounded shape (i.e., cylindrical) due to the selective etching process for completely removing the epitaxial layers 124a and 124b. In that case, the resultant epitaxial layers 124a and 124b can be called nanowires.

In some embodiments, the epitaxial layers 122a and 122b are removed by using a selective dry etching process by using, for example, CF₄ as etching gases. In some embodiments, the epitaxial layers 122a and 122b are SiGe and the epitaxial layers 124a and 124b are silicon allowing for the selective removal of the epitaxial layers 122a and 122b. In some embodiments, during the selective etching processes, some portions of the epitaxial layers 124a and 124b are also etched. As such, vertical thicknesses of the openings are greater than the thicknesses of the epitaxial layers 122a and 122b.

Interfacial layers 212 are formed around the epitaxial layers 124a and 124b. In some embodiments, the interfacial layers 212 may include a dielectric material such as silicon oxide (SiO₂), HfSiO, or silicon oxynitride (SiON). The interfacial layers 212 may be formed by chemical oxidation, thermal oxidation, atomic layer deposition (ALD), chemical vapor deposition (CVD), and/or other suitable method. In some embodiments, when the interfacial layers 212 are formed by oxidation, the interfacial layers 212 are grown on the surfaces of semiconductor materials, such as the epitaxial layers 124a and 124b.

Thereafter, high-k gate dielectric layers 214 are formed to cover the interfacial layers 212. High-k gate dielectrics include dielectric materials having a high dielectric constant, for example, greater than that of thermal silicon oxide (˜3.9). The high-k gate dielectric layers 214 may include hafnium oxide (HfO₂). Alternatively, the high-k gate dielectric layers 214 may include other high-k dielectrics, such as hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO₂), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), silicon nitride (Si₃N₄), oxynitrides (SiON), and combinations thereof. The high-k gate dielectric layers 214 may be formed by atomic layer deposition (ALD), chemical vapor deposition (CVD), and/or other suitable method.

Next, work function metal layers 216 are deposited in the gate trenches and fill the gate trenches. The work function metal layers 216 may include work function metals to provide a suitable work function for the gate structures MGB. For a p-type FET, the work function metal layers 216 may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. The work function metal layer 216 may be formed by atomic layer deposition (ALD), chemical vapor deposition (CVD), and/or other suitable method. Subsequently, one or more CMP processes are performed to remove excessive gate materials.

After the formation of the work function metal layers 216, the work function metal layers 216 are etched back by using an etching process, and the top portions of the high-k gate dielectric layers 214 are exposed. Subsequently, another work function metal layers 218 are deposited in the gate trench and over the work function metal layers 216 and fill the gate trenches. For an n-type FET, the work function metal layers 218 may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials.

Therefore, the interfacial layers 212, the high-k gate dielectric layers 214, and the work function metal layer 216 form gate structures MGB, and the interfacial layers 212, the high-k gate dielectric layers 214, and the work function metal layer 218 form gate structures MGT over the gate structure MGB.

Reference is made to FIGS. 14A and 14B. After the formation of the gate structures MGB and MGT as shown in FIGS. 13A and 13B, an etching back process is optionally performed to etch back the gate structures MGT, resulting in recesses over the etched-back gate structures MGT. In some embodiments, because the materials of the gate structures MGT have a different etch selectivity than the gate spacers 150, a selective etching process may be performed to etch back the gate structures MGT to lower the gate structures MGT. As a result, the top surfaces of the gate structures MGT may be at a lower level than the top surfaces of the gate spacers 150.

Subsequently, a dielectric cap layer is deposited over the substrate 110 until the recess is overfilled. The dielectric cap layer includes SiNₓ, AlₓO_{y}, AlON, SiOₓC_{y}, SiCₓN_{y}, boron nitride (BN), boron carbonitride (BNC), combinations thereof or the like, and is formed by a suitable deposition technique such as CVD, plasma-enhanced CVD (PECVD), ALD, remote plasma ALD (RPALD), plasma-enhanced ALD (PEALD), combinations thereof or the like. A CMP process is then performed to remove the cap layer outside the recess, leaving portions of the dielectric cap layer in the recesses to serve as dielectric cap 220. The dielectric caps 220 are in direct contact with the gate structures MGT as shown in FIGS. 14A and 14B.

Next, openings are formed in the second ILD layer 195. The opening exposes the second source/drain epitaxial structures 175. Source/drain contacts 230 are then respectively formed in the openings. In some embodiments, prior to the formation of the source/drain contacts 230, metal alloy layers are formed in the openings and on the exposed portions of the second source/drain epitaxial structures 175. Each of the source/drain contacts 230 is connected to the second source/drain epitaxial structure 175. Formation of the source/drain contacts 230 includes depositing one or more conductive (e.g., metal) materials overfilling the openings and then performing a CMP process to remove excessive metal materials outside the openings.

As such, the semiconductor device 100 is formed. As shown in FIGS. 14A and 14B, the semiconductor device 100 includes bottom (nanostructure) transistors BT and top (nanostructure) transistors TT over the bottom transistors BT, respectively. The stacked top transistor TT and bottom transistor BT form a CFET.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the etching uniformity of cut fin recesses can be improved by adjusting the morphology of the top surface of the bottom layer. Specifically, the morphology of the top surface of the bottom layer can be adjusted by designing the sizes of the first openings and the second openings.

According to some embodiments, a method includes forming first fin structures and second fin structures over a substrate. The first fin structures are distributed denser than the second fin structures. A first bottom layer of a multi-layer photoresist is deposited over the substrate to cover the first fin structures and the second fin structures. First openings are formed in the first bottom layer and over the first fin structures. Second openings are formed in the first bottom layer and over the second fin structures. A second bottom layer of the multi-layer photoresist is deposited over the substrate and fills the first openings and the second openings. A top surface of the second bottom layer directly over the first fin structures is lower than a top surface of the second bottom layer directly over the second fin structures. A photoresist layer of the multi-layer photoresist is deposited over the second bottom layer. The first fin structures and the second fin structures are patterned by using the multi-layer photoresist as an etch mask. A complementary FET including channel layers of one of the first fin structures is formed after patterning the first fin structures and the second fin structures.

According to some embodiments, a method includes forming a first fin structure over a first region of a substrate and forming a second fin structure over a second region of the substrate. A first bottom anti-reflective coating (BARC) layer is deposited over the substrate to cover the first region and the second region. A top surface of the first BARC layer over the first region is higher than a top surface of the first BARC layer over the second region. The first BARC layer is patterned to form first openings and second openings in the BARC layer. A second BARC layer is deposited over the first BARC layer after the first BARC layer is patterned. A top surface of the second BARC layer over the first region is lower than a top surface of the second BARC layer over the second region. A photoresist layer is deposited over the second BARC layer. The first fin structure and the second fin structure are patterned by using the photoresist layer, the second BARC layer, and the first BARC layer as etch masks to form a first recess in the first fin structure and a second recess in the second fin structure. A complementary FET including channel layers of the first fin structure is formed.

According to some embodiments, a method includes forming first fin structures and second fin structures over a substrate. A first bottom layer of a multi-layer photoresist is deposited over the substrate. First openings are formed in the first bottom layer and directly over the first fin structures. Second openings are formed in the first bottom layer and directly over the second fin structures. A second bottom layer of the multi-layer photoresist is deposited over the first bottom layer and covers the first openings and the second openings. A vertical distance between a top surface of the second bottom layer and a top surface of one of the first fin structures is less than a vertical distance between the top surface of the second bottom layer and a top surface of one of the second fin structures. A photoresist layer of the multi-layer photoresist is deposited over the second bottom layer. The first fin structure and the second fin structure are patterned by using the multi-layer photoresist as an etch mask. A complementary FET including channel layers of one of the first fin structure is formed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming first fin structures and second fin structures over a substrate, wherein the first fin structures are distributed denser than the second fin structures;
depositing a first bottom layer of a multi-layer photoresist over the substrate to cover the first fin structures and the second fin structures;
forming first openings in the first bottom layer and over the first fin structures;
forming second openings in the first bottom layer and over the second fin structures;
depositing a second bottom layer of the multi-layer photoresist over the substrate and filling the first openings and the second openings, wherein a top surface of the second bottom layer directly over the first fin structures is lower than a top surface of the second bottom layer directly over the second fin structures;
depositing a photoresist layer of the multi-layer photoresist over the second bottom layer;
patterning the first fin structures and the second fin structures by using the multi-layer photoresist as an etch mask; and
after patterning the first fin structures and the second fin structures, forming a complementary FET including channel layers of one of the first fin structures.

2. The method of claim 1, wherein sizes of the first openings are larger than sizes of the second openings.

3. The method of claim 2, wherein the sizes of the first openings are larger than sizes of the second openings by about 10 times to about 10000 times.

4. The method of claim 1, wherein sizes of the first openings are different but of the same order of magnitude.

5. The method of claim 1, wherein sizes of the first openings are larger than a width of one of the first fin structures.

6. The method of claim 1, wherein sizes of the second openings are larger than a width of one of the second fin structures.

7. The method of claim 1, wherein a distance between the first openings are narrower than a distance between the second openings.

8. The method of claim 1, wherein a distance between the second openings is equal to or larger than a size of one of the second openings.

9. The method of claim 1, wherein the top surface of the second bottom layer directly over the first fin structures is lower than the top surface of the second bottom layer directly over the second fin structures by a vertical distance in a range of about 10 nm and about 100 nm.

10. The method of claim 1, wherein the first bottom layer and the second bottom layer have substantially the same materials and compositions.

11. A method comprising:
forming a first fin structure over a first region of a substrate;
forming a second fin structure over a second region of the substrate;
depositing a first bottom anti-reflective coating (BARC) layer over the substrate to cover the first region and the second region, wherein a top surface of the first BARC layer over the first region is higher than a top surface of the first BARC layer over the second region;
patterning the first BARC layer to form first openings and second openings in the first BARC layer;
after patterning the first BARC layer, depositing a second BARC layer over the first BARC layer, wherein a top surface of the second BARC layer over the first region is lower than a top surface of the second BARC layer over the second region;
depositing a photoresist layer over the second BARC layer;
patterning the first fin structure and the second fin structure by using the photoresist layer, the second BARC layer, and the first BARC layer as etch masks to form a first recess in the first fin structure and a second recess in the second fin structure; and
forming a complementary FET including channel layers of the first fin structure.

12. The method of claim 11, wherein sizes of the first openings are larger than sizes of the second openings.

13. The method of claim 11, wherein a depth of one of the first openings is in a range of about 10 nm and about 100 nm.

14. The method of claim 11, wherein the first openings and the second openings do not expose the first fin structure and the second fin structure.

15. The method of claim 11, further comprising:
forming isolation structures in the first recess and the second recess prior to forming the complementary FET.

16. The method of claim 11, further comprising:
depositing a middle layer over the second BARC layer prior to depositing the photoresist layer.

17. A method comprising:
forming first fin structures and second fin structures over a substrate;
depositing a first bottom layer of a multi-layer photoresist over the substrate;
forming first openings in the first bottom layer and directly over the first fin structures;
forming second openings in the first bottom layer and directly over the second fin structures;
depositing a second bottom layer of the multi-layer photoresist over the first bottom layer and covering the first openings and the second openings, wherein a vertical distance between a top surface of the second bottom layer and a top surface of one of the first fin structures is less than a vertical distance between the top surface of the second bottom layer and a top surface of one of the second fin structures;
depositing a photoresist layer of the multi-layer photoresist over the second bottom layer;
patterning the first fin structure and the second fin structure by using the multi-layer photoresist as an etch mask; and
forming a complementary FET including channel layers of one of the first fin structure.

18. The method of claim 17, wherein a size of one of the first openings most near the second fin structures is smaller than a size of another one of the first openings over a center of the first fin structures.

19. The method of claim 17, wherein the first openings are formed by using an etching process implementing CF₄ and SiCl₄.

20. The method of claim 17, wherein a vertical distance between a top surface of the first bottom layer and the top surface of said one of the first fin structures is greater than a vertical distance between a top surface of the first bottom layer and the top surface of said one of the second fin structures.
